(19) United States
(12) Patent Application Publication
(10) Pub. No.: US 2010/0221860 A1
(43) Pub. Date: Sep. 2, 2010

(54) PRECISION MICRO-ELECTROMECHANICAL SENSOR (MEMS) MOUNTING IN ORGANIC PACKAGING

(76) Inventors: Noureddine Hawat, Woburn, MA (US); Peter R. Nuytkens, Melrose, MA (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/488,257

(22) Filed: Jun. 19, 2009

Related U.S. Application Data
(60) Provisional application No. 61/074,051, filed on Jun. 19, 2008.

(51) Int. Cl. H01L 21/56

(52) U.S. Cl. 438/51; 257/E21.502

(57) ABSTRACT

Apparatus and methods for mounting micro-electromechanical (MEMS) sensors in three dimensions, using horizontal and vertical substrates.

### CROSS-REFERENCE TO RELATED APPLICATION

This application claims priority to and the benefit of U.S. Provisional Application No. 61/074,051, filed on Jun. 19, 2008, the entire disclosure of which is hereby incorporated herein by reference.

### FIELD OF THE INVENTION

The present invention relates, generally, to the packaging of micro-electromechanical (MEMS) devices and, more specifically, to the mounting of precision MEMS sensors in three dimensions.

### BACKGROUND

Modern consumer and commercial electronic device design has undergone a trend towards miniaturization and the incorporation of multiple disparate functionalities. In particular, single-chip-scale packages increasingly tend to include multiple small devices for a plurality of functions. Many applications call for the incorporation of two- and three-dimensional navigation technology into such compact devices. Two- and three-dimensional sensors suitable for that purpose include magnetic sensors (also referred to as magnetometers) and/or tilt sensors (also referred to as accelerometers). Preferably, these sensors are of minimum height along an axis perpendicular to the chip surface (the Z-axis) and compact in directions parallel to the chip surface (i.e., parallel to the XY-plane). Vertical mounting is needed to align sensors along the X-, Y-, and Z-axes. However, mounting Z-axis accelerometers or magnetometers along the z-axis can be very challenging for the packaging industry, especially for mass market applications that have space limitations. Current cost-sensitive, high-volume, standard mounting processes fail to facilitate mounting vertical sensors for applications with limited space. Accordingly, there is an emerging need for the simple, low-cost vertical and horizontal mounting of MEMS devices at precise angles in a chip-scale package.

### SUMMARY

The present invention provides, in various embodiments, processes and methods for integrating MEMS sensors with precise location and/or orientation in X-, Y-, and Z-direction into low-cost organic chip-scale packages. In certain embodiments, the method attains structures having an overall height of less than about 0.8 mm, a width of less than about 4 mm, and a length of less than about 6 mm. Various embodiments exploit the surface tension of solder to align a Z-axis-mounted MEMS device onto, or into a hole formed in, the X-Y surface plane of a substrate.

In a first aspect, the invention provides an apparatus for precision MEMS mounting in organic packaging. In various embodiments, the apparatus includes a vertical sensor circuit assembly and a horizontal circuit assembly. The vertical sensor circuit assembly includes a MEMS device surface-mounted to a substrate. The substrate has an array of connection pads on a first side, a dummy set of connection pads on the opposite side, and conductive leads between the array and bottom edge lead pads of the substrate. The horizontal circuit assembly includes a horizontal die and the vertical sensor circuit assembly, both surface-mounted to a substrate having conductive leads with each of the horizontal die and the vertical sensor circuit assembly. Solder surface tension is used to align the horizontal die and the vertical sensor circuit assembly to the horizontal circuit assembly. In some embodiments, the distance between the bottom edge and the top edge of the vertical sensor circuit assembly is less than about 0.8 mm, and the height of the horizontal circuit assembly is less than about 0.8 mm. The MEMS device may be a hermetic sealed cavity device.

In a second aspect, the invention provides a method for precision MEMS mounting in organic packaging. The method includes patterning a first side of a Z-axis substrate with bond pads corresponding to the MEMS device; patterning a first side of the MEMS device with metal contacts for mounting to the first side of the Z-axis substrate; placing the first side of the MEMS device in contact with the first side of the Z-axis substrate; reflowing the MEMS device and the Z-axis substrate at a first temperature, and patterning the first side of an XY-axis substrate with bond pads corresponding to the Z-axis substrate. The patterning on the first side of the XY-axis substrate is spread slightly outward from the center of mass of the Z-axis substrate. The MEMS device may be a hermetic sealed cavity device. While placing the MEMS device, optical pattern recognition may be used to orient the device.

In various embodiments, the method further includes patterning the opposite side of the Z-axis substrate with dummy lead pad; reflowing the Z-axis substrate and the XY-axis substrate at a temperature lower than the first temperature; and/or adding solder mask to one or both sides of the Z-axis substrate. In certain embodiments, the method moreover includes patterning a second side of the MEMS device with metal contacts for mounting to the first side of a second Z-axis substrate; and patterning a first side of a second Z-axis substrate with bond pads corresponding to the second side of the MEMS device for mounting, wherein the reflowing of the MEMS device at a first temperature causes the MEMS device to assume a perpendicular orientation between the first and second Z-axis substrates. In these embodiments, a hole may be cut in the XY-substrate, and the MEMS device may be positioned in the hole in the XY-substrate.

### BRIEF DESCRIPTION OF THE DRAWINGS

The foregoing discussion will be understood more readily from the following detailed description of the invention when taken in conjunction with the accompanying drawings, in which:

FIGS. 1A and 1B are schematic side views of apparatus in accordance with various embodiments;

FIG. 2A is a set of cross-sectional views illustrating the artwork on various surfaces of substrates utilized in the apparatus of FIGS. 1A and 1B;

FIG. 2B is a schematic drawing showing the different layers of a Z-axis substrate in accordance with various embodiments;

FIG. 2C is a schematic drawing showing the different layers of an XY-substrate in accordance with various embodiment;

FIG. 3 is a flow chart illustrating a method in accordance with various embodiments;

FIG. 4 is a schematic side view of an apparatus including a Z-axis MEMS sensor directly soldered to an XY-substrate in accordance with one embodiment;

FIG. 5 is a schematic side view of an apparatus including a Z-axis MEMS sensor embedded in a hole formed in an XY-substrate in accordance with one embodiment; and

FIG. 6 is a schematic side view of an apparatus including a Z-axis MEMS sensor directly soldered to an XY-substrate and including multiple rows of connections in accordance with one embodiment.

### DETAILED DESCRIPTION OF THE INVENTION

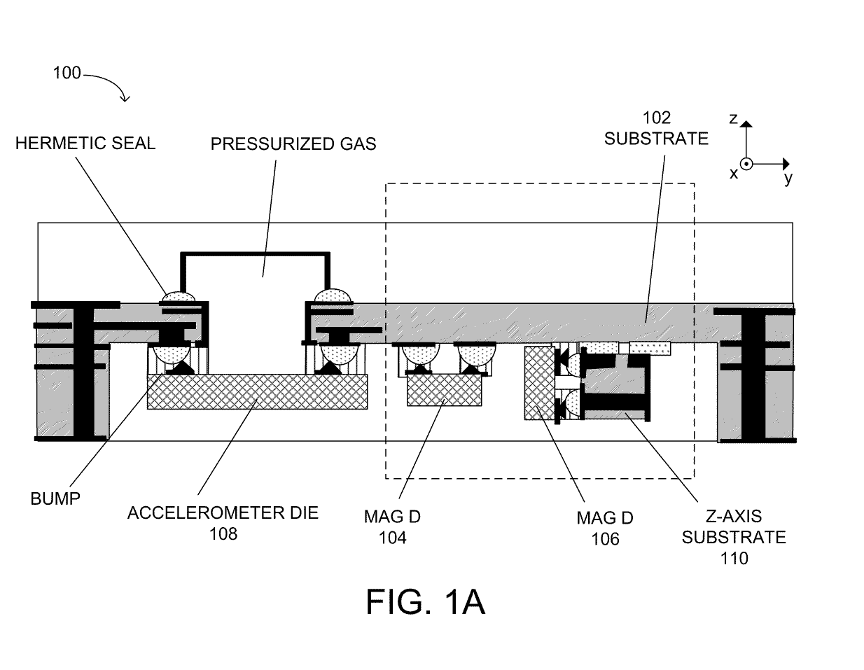

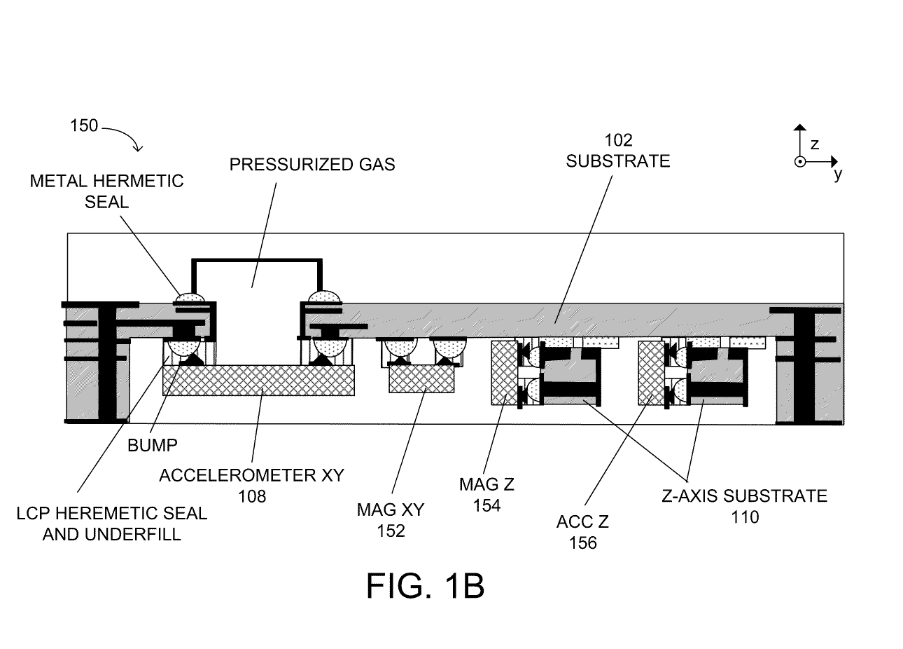

FIG. 1A illustrates, in cross section, an exemplary apparatus 100 for integrating MEMS sensors in organic packaging. The apparatus includes a substrate 102 and, mounted thereon, various MEMS sensors 104, 106, 108. A first MEMS sensor 104 is a magnetometer that is soldered to a bottom surface (hereinafter also referred to as side B) of the substrate 102 and oriented horizontally, i.e., parallel to the XY-substrate. A second MEMS sensor 106, also a magnetometer, is vertically oriented and mounted flush to a Z-axis substrate 110. The Z-axis substrate 110 itself, with a face perpendicular to the surface whereon the sensor is mounted, is soldered to side B of the XY-substrate 102. The third MEMS sensor 108 is an accelerometer die that is horizontally mounted to side B of the XY-substrate 102, and enclosed by a hermetically sealed cavity. Detail on the structure and manufacture of hermetic seal cavity devices is provided in a U.S. patent application Ser. No. 12/488,137, filed on even date herewith, which is hereby incorporated herein by reference in its entirety.

Another exemplary apparatus (150) in accordance with various embodiments is illustrated in FIG. 1B. In addition to a cavity-encapsulated, horizontal XY-accelerometer 108 and a horizontal XY-magnetometer 152, apparatus 150 includes two vertical MEMS devices—a Z-magnetometer 154 and a Z-accelerometer 156, each of which is attached to the XY-substrate 102 via a Z-axis substrate 110.

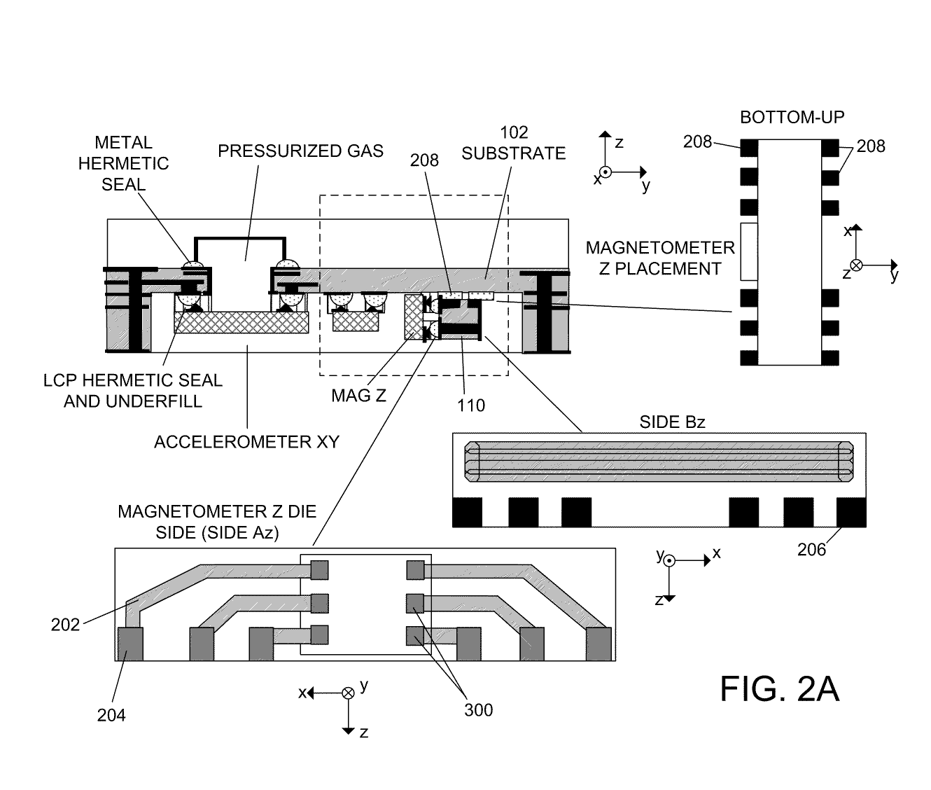

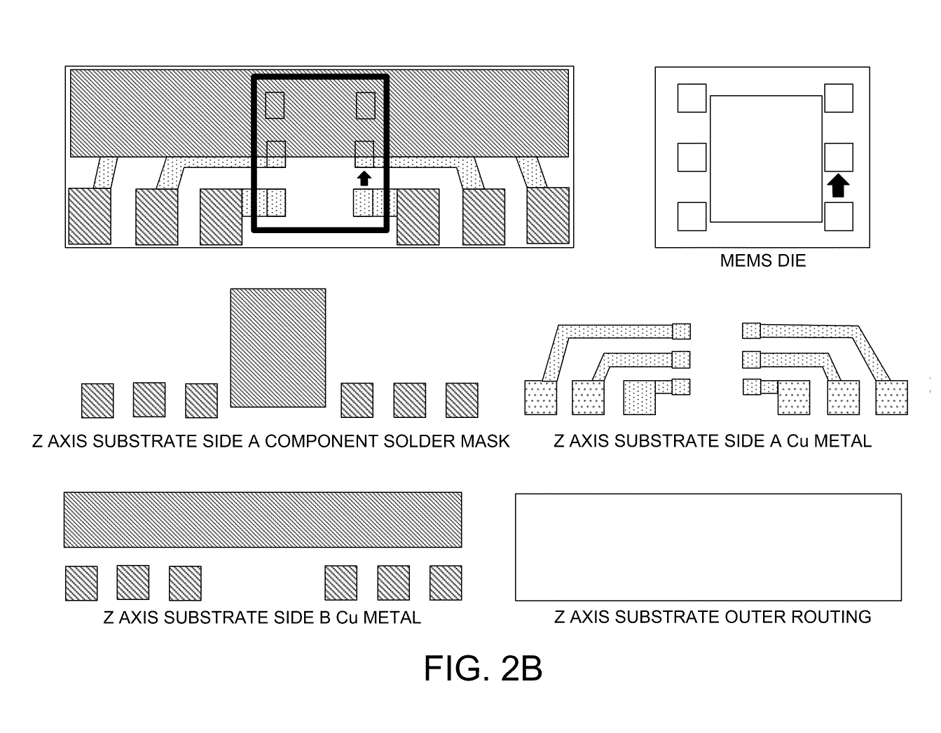

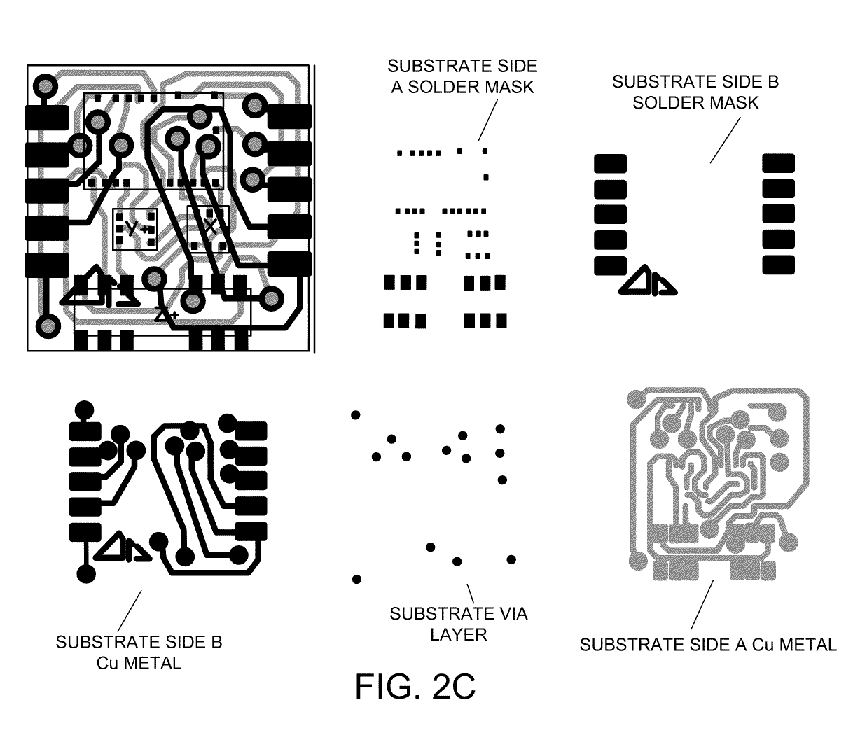

FIG. 2A illustrates the artwork on the MEMS-die side of the Z-axis substrate 110 (side A_{z}) and on the opposite side of the Z-axis substrate (side B_{z}), as well as the artwork on side B of the XY-substrate 102 in a region where the Z-axis substrate 110 is attached. The die side of the Z-axis substrate is patterned with bond pads 200 corresponding to the Z-axis MEMS device mounted thereon. Conductive traces 202 redistribute the signals from these bond pads to the bottom edge lead pads 204 of the Z-axis substrate 110. Dummy lead pads 206 are patterned on side A_{z} of the Z-axis substrate for symmetry and balance of force. The XY-substrate 102 is patterned with bond pads 208 corresponding to the Z-axis substrate 110, and additional bond pads corresponding to the X- and Y-axis MEMS devices mounted thereon. Conductive traces redistribute the signals from these bond pads to the lead edge pads of the substrate 102. The bond pads of the XY-substrate 102 spread slightly outward from the center of mass of the region wherein the horizontal MEMS devices and Z-axis substrates are placed. During assembly of the apparatus, this spreading creates surface tension when the solder is wetted, which in turn pulls the MEMS devices and Z-axis substrates flush against the XY-substrate, thereby forcing an automatic perpendicular alignment of the MEMS devices and the Z-axis substrates to within the tolerance of the diced surfaces. FIG. 2B illustrates in more detail the various layers and the artwork of the Z-axis substrate 110; and FIG. 2C shows the various layers of the XY-substrate 102 and the combined artwork for the apparatus.

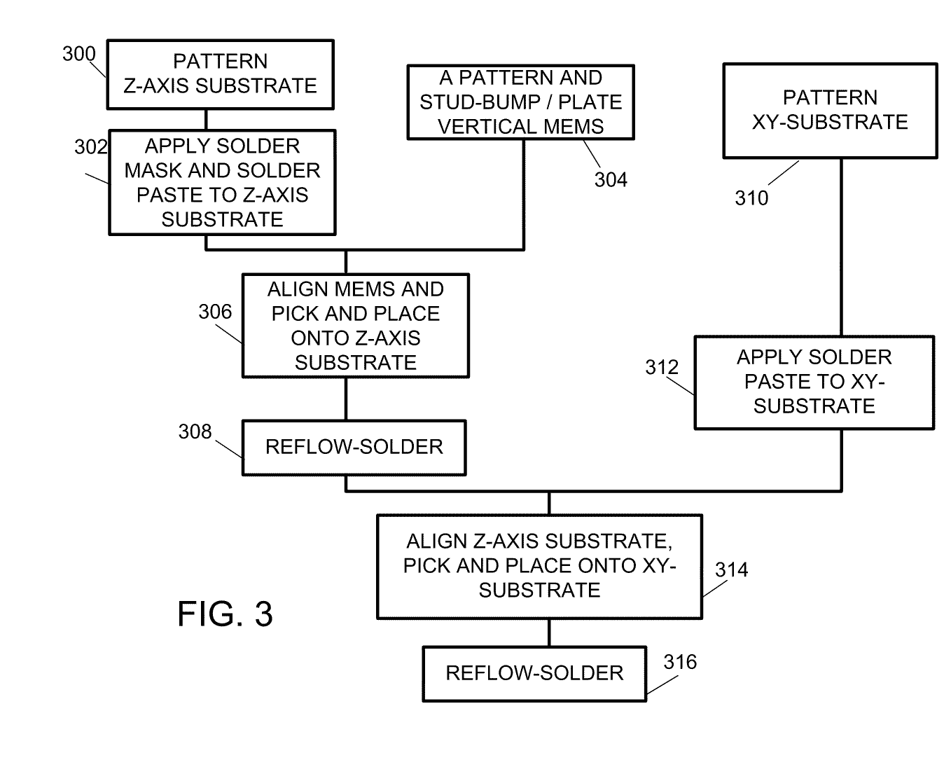

Apparatus 100, 150 and similar structures may be built according to the method illustrated in FIG. 3. The method includes patterning sides A_{z} and B_{z} of the Z-axis substrate 110 as illustrated in FIG. 2 (step 300). In step 302, solder mask is applied to both sides of the Z-axis substrate to control and isolate the bond pads 200 and the lead pads 204, 206 and constrain the wicking action of solder during reflow in a later step. Further, SnSbCu solder paste with a liquidus temperature from about 240° C. to about 260° C. is applied to side A_{z} over the bond pads 206 only.

The vertical MEMS devices (e.g., magnetometers 154 and/or 156) are patterned and stud-bumped or plated with gold or copper (step 304), and then aligned and pick-and-placed onto the Z-axis substrate 110 (step 306). Optical pattern recognition may be used during placement to recognize and orient the rotation of each device around an axis normal to side A_{z} within less than one degree. A vacuum head may be used to pick up the MEMS devices and place them onto the Z-axis substrate 110, maintaining a Z-tilt of less than one degree with respect to the substrate surface. Next, the Z-axis substrate 110 with the aligned devices is reflowed at a temperature between 260° C. and 340° C. (step 308), allowing for later end-customer green process assembly with SnAgCu solder having a liquidus temperature of from about 220° C. to about 230° C. The Z-axis substrate 110 with aligned MEMS devices is then diced, and transfer-rotated 90 degrees into holding trays in preparation of the pick-and-place onto the XY-substrate.

In step 310, the XY-substrate 102 is patterned with bond pads corresponding to the horizontal MEMS devices (e.g., magnetometers 104 and/or accelerometer dies 108) and the Z-substrates 110 to be mounted. Then, solder mask is added to sides A and B to isolate the wicking action of the solder. Solder paste is applied to side A of the XY-substrate (step 312), and the XY- and Z-mounted MEMS devices are pick-and-placed into position (step 314). Again, optical pattern recognition may be employed with the pick-and-place to recognize and orient the rotation of the devices and Z-substrates in X- and Y-direction (i.e., around an axis normal to side A) within less than one degree. The vacuum head picks up the devices and places them onto the XY-substrate, maintaining a tilt of less than 1 degree with respect to the substrate surface. In step 316, the XY-substrate and devices mounted thereon is reflowed at a temperature between about 220° C. to about 230° C. (step 316).

The apparatus and method described above may be modified in various ways. For example, the Z-mounted MEMS device may be a hermetic sealed cavity device, such as an accelerometer. The vertical mounting of a hermetic sealed cavity device may be accomplished as described above, using additional weights to balance the pick-and-place Z-substrate so that the solder wicking process results in perpendicular alignment to the XY-substrate.

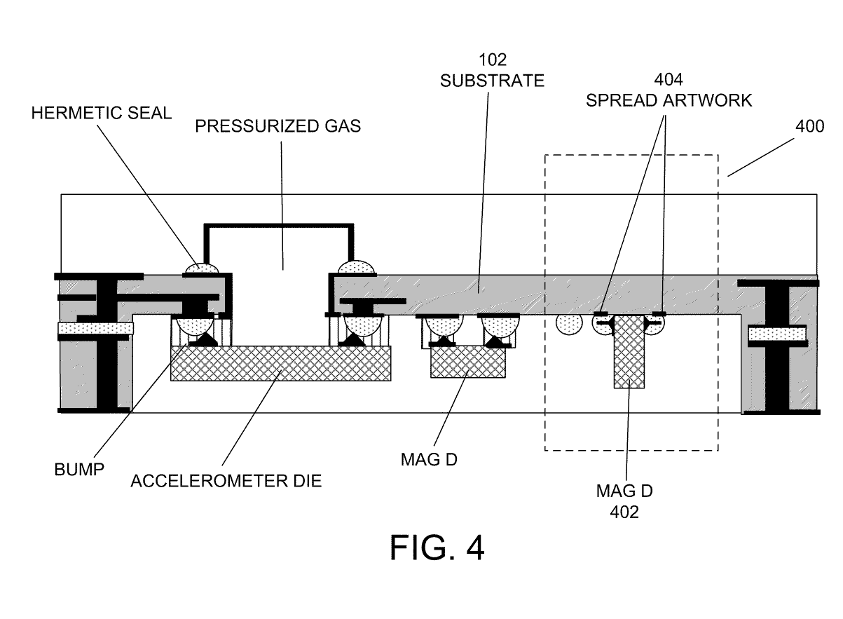

In an alternative embodiment, a Z-axis MEMS device may be directly soldered to the XY-substrate, without using a Z-axis substrate. The resulting structure 400 is illustrated schematically in FIG. 4. In this embodiment, the bond pads of the Z-mounted MEMS die 402 are arranged to be on one side of the die, and the back side of the die is plated with a similar dummy pattern. The die is stud-bumped or plated on the front and back sides. Then, the die is rotated by ninety degrees, and pick-and-placed onto the substrate 102. The substrate is reflowed against the spread artwork 404 to force an automatic perpendicular alignment of the MEMS device 402 and the substrate 102.

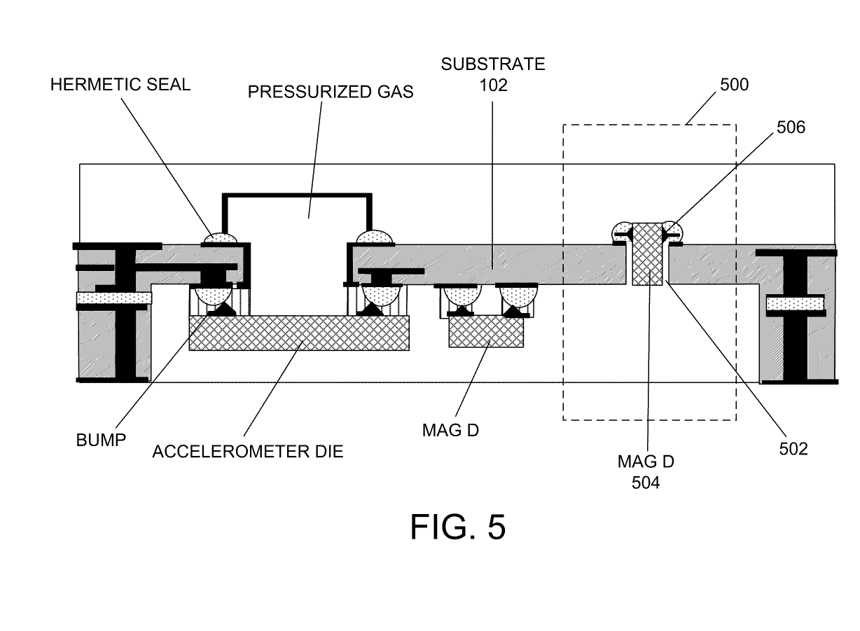

In another embodiment, the Z-mounted MEMS device is integrated into a hole in the substrate, resulting in a structure 500 shown in FIG. 5. The hole 502 may be laser-cut or mechanically routed in the XY-substrate 102. The Z-mounted MEMS device 504 is pick-and-placed into the hole 502, and suspended by stud bumps 506 on the device 504. Solder is dispensed over the bond pads with the stud bump wires and then reflowed. To guarantee perpendicular alignment, a boat is used under the substrate during reflow.

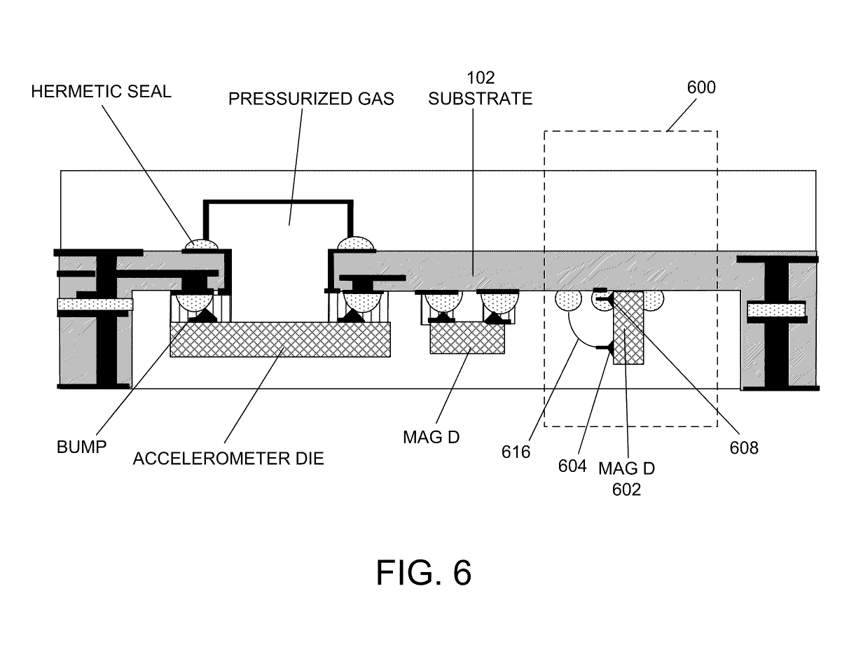

In yet another embodiment, illustrated in FIG. 6 by structure 600, the Z-mounted MEMS device 602 is attached to the XY-substrate 102 as in FIG. 4, but includes addition electric connections. Again, bond pads are arranged to be on one side of the MEMS die 602, and the back side of the die 602 is plated with a similar dummy pattern. The die 602 is stud-bumped or plated on both sides. The upper connections 604 to the die 602 are wire-bonded in an open ark 606 in a buttress fashion to make a contact on pads one row beyond the lower set of connections 608. The die is rotated by ninety degrees, and pick-and-placed onto the substrate 102. The substrate is reflowed against the spread artwork to force an automatic perpendicular alignment of the MEMS device 602 and the substrate 102.

Having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. An apparatus for precision micro-electromechanical sensor (MEMS) mounting in organic packaging, the apparatus comprising:
a vertical sensor circuit assembly comprising a MEMS device surface-mounted to a substrate having an array of connection pads on a first side, a dummy set of connection pads on the opposite side, and conductive leads between the array and bottom edge lead pads of the substrate; and
a horizontal circuit assembly comprising a horizontal die and the vertical sensor circuit assembly both surface-mounted to a substrate having conductive leads with each of the horizontal die and the vertical sensor circuit assembly,
wherein solder surface tension is used to align the horizontal die and the vertical sensor circuit assembly to the horizontal circuit assembly.

2. The apparatus of claim 1 wherein the distance between the bottom edge and the top edge of the vertical sensor circuit assembly is less than about 0.8 mm and the height of the horizontal circuit assembly is less than about 0.8 mm.

3. The apparatus of claim 1 wherein the MEMS device is a hermetic sealed cavity device.

4. A method for precision micro-electromechanical sensor (MEMS) mounting in organic packaging, the method comprising:
patterning a first side of a Z-axis substrate with bond pads corresponding to the MEMS device;
patterning a first side of the MEMS device with metal contacts for mounting to the first side of the Z-axis substrate;
placing the first side of the MEMS device in contact with the first side of the Z-axis substrate;
reflowing the MEMS device and the Z-axis substrate at a first temperature; and
patterning the first side of a XY-axis substrate with bond pads corresponding to the Z-axis substrate,
wherein the patterning on the first side of the XY-axis substrate is spread slightly outward from the center of mass of the Z-axis substrate.

5. The method of claim 4 further comprising patterning the opposite side of the Z-axis substrate with dummy lead pads.

6. The method of claim 4 further comprising reflowing the Z-axis substrate and the XY-axis substrate at a temperature lower than the first temperature.

7. The method of claim 4 further comprising adding solder mask to the first side of the Z-axis substrate.

8. The method of claim 5 further comprising adding solder mask to the opposite side of the Z-axis substrate.

9. The method of claim 4 where placing the MEMS device comprises orienting the device using optical pattern recognition.

10. The method of claim 4 further comprising:
patterning a second side of the MEMS device with metal contacts for mounting to the first side of a second Z-axis substrate; and
patterning a first side of a second Z-axis substrate with bond pads corresponding to the second side of the MEMS device for mounting,
wherein the reflowing of the MEMS device at a first temperature causes the MEMS device to assume a perpendicular orientation between the first and second Z-axis substrates.

11. The method of claim 10 further comprising:
cutting a hole in the XY-substrate; and
positioning the MEMS device in the hole in the XY substrate.

12. The method of claim 4 wherein the MEMS device is a hermetic sealed cavity device.
